(19) United States
(12) Patent Application Publication
(10) Pub. No.: US 2015/0137345 A1
(43) Pub. Date: May 21, 2015

(54) SEMICONDUCTOR PACKAGE HAVING HEAT SPREADER

(71) Applicant: Samsung Electronics Co., Ltd., Suwon-si (KR)

(72) Inventors: Eun-Kyoung CHOI, Hwaseong-si (KR); Sang-Uk HAN, Hwaseong-si (KR); Tae-Je CHO, Hwaseong-si (KR)

(21) Appl. No.: 14/504,309

(22) Filed: Oct. 1, 2014

(30) Foreign Application Priority Data
Nov. 21, 2013 (KR) 10-2013-0142305

(51) Int. Cl. H01L 25/065; H01L 23/538; H01L 23/367

(52) U.S. Cl. CPC H01L 25/0657; H01L 23/3675; H01L 23/5384; H01L 2225/06513; H01L 2225/06517; H01L 2225/06541; H01L 2225/06589
USPC 257/713

(57) ABSTRACT

A semiconductor package includes a heat spreader. The semiconductor package includes a substrate, a first semiconductor chip disposed on the substrate, and a second semiconductor chip disposed on the first semiconductor chip. The heat spreader may be formed on the first semiconductor chip. A thermal interfacial material (TIM) layer may be formed to be in contact with the first semiconductor chip and the heat spreader and may cover side surfaces of the second semiconductor chip. Heat generated by the first semiconductor chip may be emitted through the TIM layer and the heat spreader. Thermal stress caused by a difference in coefficients of thermal expansion (CTEs) between the substrate and the first semiconductor chip may be distributed to ensure structural stability.

### CROSS-REFERENCE TO RELATED APPLICATION

This application claims priority under 35 U.S.C. §119 to Korean Patent Application No. 10-2013-0142305 filed on Nov. 21, 2013, the disclosure of which is hereby incorporated by reference in its entirety.

### BACKGROUND

1. Field

Embodiments of the inventive concepts provide a semiconductor package having a heat spreader.

2. Description of Related Art

In semiconductor packages, when heterogeneous memory/logic devices are stacked in a single package, high power consumption while driving the devices may result in heat being generated in the package. Excessive heat may degrade the reliability of the semiconductor packages.

### SUMMARY

Embodiments of the inventive concepts provide a semiconductor package capable of effectively emitting heat from the semiconductor package.

The technical objectives of the inventive concepts are not limited to the specific embodiments disclosed herein. Other objectives may become apparent to those of ordinary skill in the art based on the following description.

In accordance with an aspect of the inventive concepts, a semiconductor package may include a substrate, a first semiconductor chip disposed on the substrate, a second semiconductor chip disposed on the first semiconductor chip, a heat spreader disposed on the first semiconductor chip, and a thermal interfacial material (TIM) layer being in contact with the first semiconductor chip and the heat spreader, the TIM layer covering one or more side surfaces of the second semiconductor chips.

The second semiconductor chip may include a first side surface and a second side surface. The TIM layer may be in contact with the first and second side surfaces of the second semiconductor chip.

The TIM layer may be formed between a top surface of the second semiconductor chip and the heat spreader.

The TIM layer may be in contact with a side surface of the first semiconductor chip.

A lower end or lower portion of the heat spreader may be arranged at a level lower than that of a bottom surface of the second semiconductor chip.

A distance between the lower end of the heat spreader and a top surface of the first semiconductor chip may be smaller than a distance between the second semiconductor chip and the first semiconductor chip.

A side surface of the first semiconductor chip may be exposed.

The first semiconductor chip may include through-silicon vias (TSVs) formed through the first semiconductor chip.

The semiconductor package may further include an underfill disposed between the substrate and the first semiconductor chip, an under-bump metallurgy (UBM) disposed on the TSVs, and bumps formed through the underfill and connected to the UBM and the substrate.

In accordance with another aspect of the inventive concepts, a semiconductor package may include a first semiconductor chip, a second semiconductor chip formed on the first semiconductor chip, and a heat spreader formed on the first semiconductor chip and configured to cover top and side surfaces of the second semiconductor chip. A lower end or lower portion of the heat spreader may be arranged at a level lower than a bottom surface of the second semiconductor chip.

The lower end of the heat spreader may be in contact with the first semiconductor chip.

A distance between the lower end of the heat spreader and a top surface of the first semiconductor chip may be smaller than a distance between the second semiconductor chip and the first semiconductor chip.

The heat spreader may have a width that is greater than a width of the first semiconductor chip.

The semiconductor package may further include a TIM layer disposed between the heat spreader and a top surface of the first semiconductor chip.

A more detailed description of these and other embodiments is included in the following detailed description and accompanying drawings.

### BRIEF DESCRIPTION OF THE DRAWINGS

The foregoing and other features and advantages of the inventive concepts will be readily apparent from the following descriptions of preferred embodiments, made with reference to the accompanying drawings, in which like reference characters refer to the same or like parts throughout the different views. The drawings are not necessarily to scale, emphasis instead being placed upon illustrating the principles of the inventive concepts. In the drawings:

FIGS. 1 through 8 are cross-sectional views of semiconductor packages according to embodiments of the inventive concepts;

FIGS. 9 through 11 are perspective views of a thermal interface material (TIM) layer structure, which may be mounted in upper layers of semiconductor packages according to embodiments of the inventive concepts;

FIG. 12 illustrates the flow of heat in a semiconductor package according to embodiments of the inventive concepts;

FIGS. 13 through 15 are somewhat schematic diagrams of various configurations of a heat spreader according to embodiments of the inventive concepts;

FIG. 16 is a cross-sectional view of a configuration of a multi-chip package (MCP) according to an embodiment of the inventive concepts;

FIG. 17 is a plan view of a first semiconductor package having hot spots according to another embodiment of the inventive concepts;

FIG. 18 is a cross-sectional view of the semiconductor package having hot spots of FIG. 17;

FIG. 19 is a cross-sectional view of a semiconductor package according to another embodiment of the inventive concepts;

FIGS. 20 through 26 are cross-sectional views of a semiconductor package illustrating a method of fabricating a semiconductor package according to embodiments of the inventive concepts;

FIGS. 27 and 28 are perspective views of an electronic device according to embodiments of the inventive concepts; and

FIG. 29 is a block diagram of an electronic device according to another embodiment of the inventive concepts.

### DETAILED DESCRIPTION OF THE EMBODIMENTS

The inventive concepts will be described more fully hereinafter with reference to the accompanying drawings, in which various embodiments of the inventive concepts are shown. This inventive concepts may, however, be embodied in many different forms and should not be construed as being limited to the specific embodiments set forth herein. Rather, these example embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on” another element or layer, it can be directly on the other element or layer or intervening elements or layers may be present. Like numbers refer to like elements throughout.

It will be understood that, although the terms first, second, etc. may be used herein to describe various elements, components, regions, layers and/or sections, these elements, components, regions, layers and/or sections should not be limited by these terms. Rather, a first element, component, region, layer or section discussed below could be termed a second element, component, region, layer or section without departing from the teachings of the inventive concepts.

Spatially relative terms, such as “top end”, “bottom end”, “lower end”, “upper end”, “top surface”, “bottom surface”, “upper”, “lower”, “above”, “beneath”, “below”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” should be interpreted to encompass both orientations. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concepts. As used herein, the singular forms “a”, “an”, and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and this specification and should not be interpreted in an idealized or overly formal sense unless expressly defined herein.

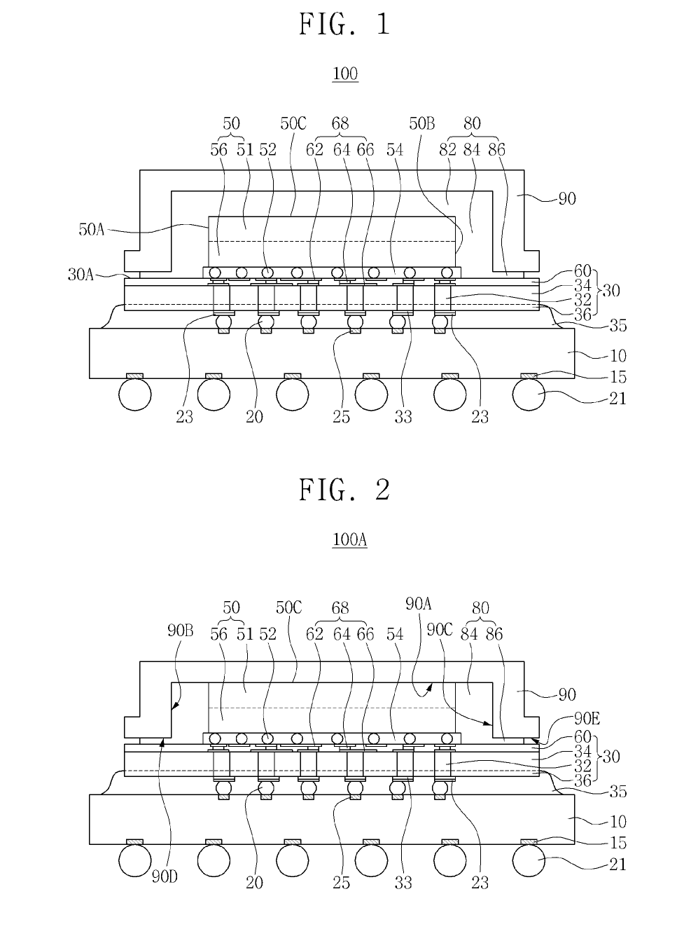

FIG. 1 is a cross-sectional view of a semiconductor package 100 according to embodiments of the inventive concepts.

Referring to FIG. 1, the semiconductor package 100 may include a substrate 10, and a first semiconductor chip 30 formed on the substrate 10. The first semiconductor chip 30 may include a redistribution layer 60, one or more through-silicon vias (TSVs) 32, a first semiconductor layer 34, and a first circuit element 36. The redistribution layer 60 may include TSV pads 66 electrically connected to TSVs 32 disposed in the first semiconductor chip 30, and may further include redistribution vias 64, and redistribution lands 62. Second bumps 52 may be formed on a top surface of the redistribution layer 60. The second bumps 52 may be connected to a second semiconductor chip 50 using a flip-chip process. The second bump 52 may include a solder material.

When viewed in cross-section, the second semiconductor chip 50 may have first and second side surfaces 50A, 50B, respectively. The TIM layer 80 may be in contact with the first and second side surfaces 50A, 50B, respectively, of the second semiconductor chip 50. A heat spreader 90 may be formed or arranged above the second semiconductor chip 50. The heat spreader 90 may have an adhesive property. The heat spreader 90 may include a highly thermally conductive material. For example, the heat spreader 90 may include one or more materials such as copper (Cu), silver (Ag), gold (Au), platinum (Pt), tin (Sn), aluminum (Al), or a combination thereof.

A thermal interface material (TIM) layer 80 may be arranged between the second semiconductor chip 50 and the heat spreader 90. The TIM layer 80 may include an upper portion 82, side portions 84, and lower portions 86. The upper portion 82 of the TIM layer 80 may be formed between the heat spreader 90 and a top surface 50C of the second semiconductor chip 50. The side portions 84 may be formed between the heat spreader 90 and side surfaces of the second semiconductor chip 50, including the first and second side surfaces 50A, 50B, respectively. The lower plate 86 may be formed between a top surface 30A of the first semiconductor chip 30 and the heat spreader 90.

The TIM layer 80 may be in contact with the first semiconductor chip 30. The TIM layer 80 may, for example, include aluminum oxide (Al₂O₃), zinc oxide (ZnO), a curing resin, or a combination thereof.

The substrate 10 may include, for example, a package printed circuit board (PCB). The substrate 10 may include a plurality of lower lines. The substrate 10 may include a substrate rigid PCB, a flexible PCB, or a rigid-flexible PCB.

A plurality of first upper lands 25 may be formed on a top surface of the substrate 10 and may be electrically connected to the first semiconductor chip 30. First lower lands 15 may be formed on a bottom surface of the substrate 10. Each of the first lower lands 15 may include a conductive tab, a finger electrode, a lead grid array (LGA), a pin grid array (PGA), or a combination thereof. The first lower lands 15 may, for instance, include copper (Cu), nickel (Ni), gold (Au), or a solder material.

External connection members 21 may be formed on the first lower lands 15 and may be configured to electrically connect the semiconductor package 100 to a motherboard. Each of the external connection members 21 may be formed of a solder material, such as a solder ball, a solder bump, or a solder paste, or a metal having a spherical shape, a mesa shape, or a pin shape, for example. The external connection members 21 may be formed in a grid type array to provide a ball grid array (BGA).

The first semiconductor chip 30 may include a first semiconductor layer 34, a redistribution layer 60, and TSVs 32. The first semiconductor layer 34 may include a semiconductor wafer. The semiconductor wafer may, for instance, include a Group-IV material or a Group III-V compound. For example, the first semiconductor layer 34 may include silicon (Si), germanium (Ge), or a gallium arsenide (GaAs).

The first semiconductor layer 34 may include a first circuit element 36 formed therein. The first circuit element 36 may, for example, include a memory element, a core circuit element, a peripheral circuit element, a logic circuit element, or a control circuit element. The memory device may include, for example, a volatile memory device, such as a dynamic random access memory (DRAM) or a static RAM (SRAM). The memory device may also, or alternatively, include a nonvolatile memory device, such as an erasable programmable read-only memory (EPROM), an electrically erasable programmable ROM (EEPROM), or a flash EEPROM. The first semiconductor layer 34 may include a circuit line configured to electrically connect first circuit elements 36. The first circuit element 36 may be formed in a lower layer of the first semiconductor chip 30 or on an upper side of the first semiconductor chip 30.

The first semiconductor chip 30 may, for example, have a thickness of about 50 μm or about 100 μm.

The first semiconductor chip 30 may have a greater horizontal length and a lower vertical height than the second semiconductor chip 50. Side surfaces of the first semiconductor chip 30 may be exposed to the outside of the semiconductor package.

The redistribution layer 60 may include a redistribution pattern 68 and an insulating layer. The redistribution pattern 68 may include a redistribution land 62, a redistribution via 64, and a TSV pad 66. The redistribution lands 62 may be electrically connected to the second bumps 52 of the second semiconductor chip 50. The TSV pad 66 may be electrically connected to the TSV 32 of the first semiconductor chip 30.

The redistribution pattern 68 of the redistribution layer 60 may include a metal layer, having a material such as doped polysilicon (doped poly-Si), tungsten (W), or aluminum (Al). The insulating layer included in the redistribution layer 60 may electrically insulate the redistribution land 62 from the TSV pad 66 and may include the redistribution via 64. The insulating layer may include materials such as silicon oxide or silicon nitride and may also include a resin, such as polyimide (PI).

In the field of semiconductor packages, the need for a wafer-level package (WLP) obtained by downscaling a package on a chip level or a system-in-package, obtained, for example, by mounting multifunctional semiconductor chips in a single semiconductor package has increased. A redistribution layer 60 may be used to embody the system-in-package or the WLP. An increase in integration density may lead to a reduction in distance between bump lands (indicated by the redistribution lands 62) on which the second bumps 52 may be electrically mounted. The reduction in the distance between the redistribution lands 62 may result in a reduction in distance between the first bumps 20. The first bumps 20 may be electrically connected to lower connection terminals 33 formed under the TSVs 32. When the distance between the first bumps 20 is reduced, a short between the first bumps 20 may occur. When the semiconductor chips 30 and 50 are stacked, pads formed in the centers of the semiconductor chips 30 and 50 may extend to edges of the semiconductor chips 30 and 50. Positions in which the first bumps 20 are adhered may be redistributed using a metal line. The first bumps 20 may have a greater size than that of the second bumps 52.

The redistribution layer 60 may be electrically connected to the redistribution lands 62 disposed over the semiconductor layer 34 of the first semiconductor chip 30, may form a metal line in a region having a low pattern density, and may be connected to external circuits outside the semiconductor package.

The TSVs 32 may penetrate the first semiconductor layer 34. Each TSV 32 may electrically connect the redistribution pattern 68 with a corresponding one of the first bumps 20. For example, the TSVs 32 may include a metal (e.g., aluminum (Al), copper (Cu), tungsten (W), or a combination thereof), poly-Si, or doped silicon. The present embodiments describe an example in which six TSVs 32 are provided. The TSVs 32 may be formed under a bottom surface of the second semiconductor chip 50.

When the first semiconductor chip 30 contains silicon as the main component, the first semiconductor chip 30 may have a coefficient of thermal expansion (CTE) of about 2 to 5 ppm/° C. The substrate 10 to which the first semiconductor chip 30 is adhered may have a CTE of about 10 to 25 ppm/° C. When the CTE of the first semiconductor chip 30 is not equal to the CTE of the substrate 10, coherence obtained by the first bump 20 may be weakened.

In the present embodiments of the inventive concepts, connection of the first semiconductor chip 30 with the heat spreader 90 of the second semiconductor chip 50 using the TIM layer 80 may ensure thermal performance of the semiconductor package 100. By ensuring thermal performance, problems resulting from high-power generation in the semiconductor package 100 may be solved. However, even if accumulation of heat in the first and second semiconductor chips 30 and 50, respectively, is solved by connecting the heat spreader 90 to the semiconductor package 100, a disparity in CTEs between the substrate 10 and the first semiconductor chip 30 may remain. By equalizing CTEs of the substrate 10 and the first semiconductor chip 30, reliability of the semiconductor package 100 may be further improved.

A disparity in CTEs between the substrate 10 and the first semiconductor chip 30 may cause shear stress between the substrate 10 and the first semiconductor chip 30. More specifically, thermal stress may be caused due to a difference in CTEs between the first semiconductor chip 30 and the substrate 10 during a reflow process of a flip-chip mounting technique. The thermal stress may induce shear stress to the first bumps 20 disposed on edges of the first semiconductor chip 30 and the substrate 10. A shear strain caused by the shear stress may be expressed through the following equation 1:

Equation 1

γ=Δ/h=L/h (α_{b}−α_{c})(Tₘₐₓ−Tₘᵢₙ)

In the foregoing equation, h is the height of the first bumps 20, L is a distance from a neutral point of the first semiconductor chip 30, α_{b} is a CTE of the substrate 10, α_{c} is a CTE of the first semiconductor chip 30, and Tₘₐₓ and Tₘᵢₙ denote a reflow temperature and room temperature, respectively. Referring to Equation 1, as the height of the first bumps 20 increases, the shear strain may be reduced. Thus, reliability of the semiconductor package 100 may be enhanced.

An underfill 35 may be used to surround the first bumps 20. The underfill 35 may fill in a space between the first semiconductor chip 30 and the substrate 10. The underfill 35 may surround and protect the first bumps 20.

A region between the first semiconductor chip 30 and the substrate 10 may include under-bump metallurgy (UBM) 23 formed on a pad of the first semiconductor chip 30 and solder formed on the UBM 23. The solder may be formed, for example, using a vacuum evaporation process or an electroplating process. The UBM 23 may be highly adhesive to the TSVs 32 of the first semiconductor chip 30. The UBM 23 may be formed on a lower connection terminal 33, which is a lower end unit of the TSV 32. The UBM 23 may be formed between the TSV 32 and the first bump 20 and may include an adhesion layer, a diffusion stop layer, and a wettable layer. The UBM 23 may prevent diffusion of a material (e.g., solder) included in the first bumps 20.

A reflow process may be performed on solders mounted on the UBM 23, to thereby form solder balls. After the solder balls are formed, an underfill 35 may be coated in regions where the solder balls are formed. The underfill 35 may serve to protect the first bump 20 and the first semiconductor chip 30 and to improve reliability of the semiconductor package 100. The underfill 35 may have a middle CTE, between CTEs of the first semiconductor chip 30 and the substrate 10. The underfill 35 may reduce thermal stress caused by a difference in CTE between the first semiconductor chip 30 and the substrate 10.

The second semiconductor chip 50 may include a second semiconductor layer 51. The second semiconductor layer 51 may include silicon, germanium, or gallium arsenide. The second semiconductor layer 51 may include second circuit elements 56 formed therein.

The second circuit elements 56 may include a memory element, a core circuit element, a peripheral circuit element, a logic circuit element, or a control circuit element. The second circuit elements 56 may also include circuit lines configured to electrically connect the second circuit elements 56. For example, a core circuit element, a peripheral circuit element, a logic circuit element, or a control circuit element may be formed in the first semiconductor chip 30, and a memory element may be formed in the second semiconductor chip 50.

The second bumps 52 may be formed under the second semiconductor layer 51. The second bumps 52 may be formed using a flip-chip process. Each of the second bumps 52 may be electrically connected to a redistribution land 62 and the second semiconductor chip 50. A first contact layer 54 may be formed to surround the second bumps 52.

The first contact layer 54 may include a die-adhesive film (DAF). The DAF may be formed using a liquid or film-type epoxy resin. For example, the first contact layer 54 may include epoxy, benzocyclobutene (BCB), or PI.

FIG. 2 is a cross-sectional view of a semiconductor package 100A according to other embodiments of the inventive concepts.

Referring to FIG. 2, the semiconductor package 100A may include a first semiconductor chip 30, a second semiconductor chip 50 formed on the first semiconductor chip 30, and a heat spreader 90 that is arranged in contact with a top surface of the second semiconductor chip 50. A TIM layer 800 may be provided in contact with at least two side surfaces of the second semiconductor chip 50. The TIM layer 80 may, for example, surround the second semiconductor chip 50. The TIM layer 80 may be formed at the same level as the second semiconductor chip 50. The TIM layer 80 may include first side portions 84 configured to surround the side surfaces of the second semiconductor chip 50 and lower portions 86 arranged on a top surface of the first semiconductor chip 30. The lower portions 86 of the TIM layer 80 may extend from the first side portions 84 of the TIM layer 80.

The heat spreader 90 may include a top surface 90A, side surfaces 90B, 90C, and bottom surfaces 90D, 90E. The top surface 90A of the heat spreader 90 may be in contact with the top surface 50C of the second semiconductor chip 50. The heat spreader 90 may rapidly emit heat generated by the top surface 50C of the second semiconductor chip 50. Since the heat spreader 90 includes a highly thermally conductive metal, the heat spreader 90 may reach the same temperature as that of the outside in a short amount of time. In the above-described process, heat generated by the second semiconductor chip 50 may be rapidly emitted.

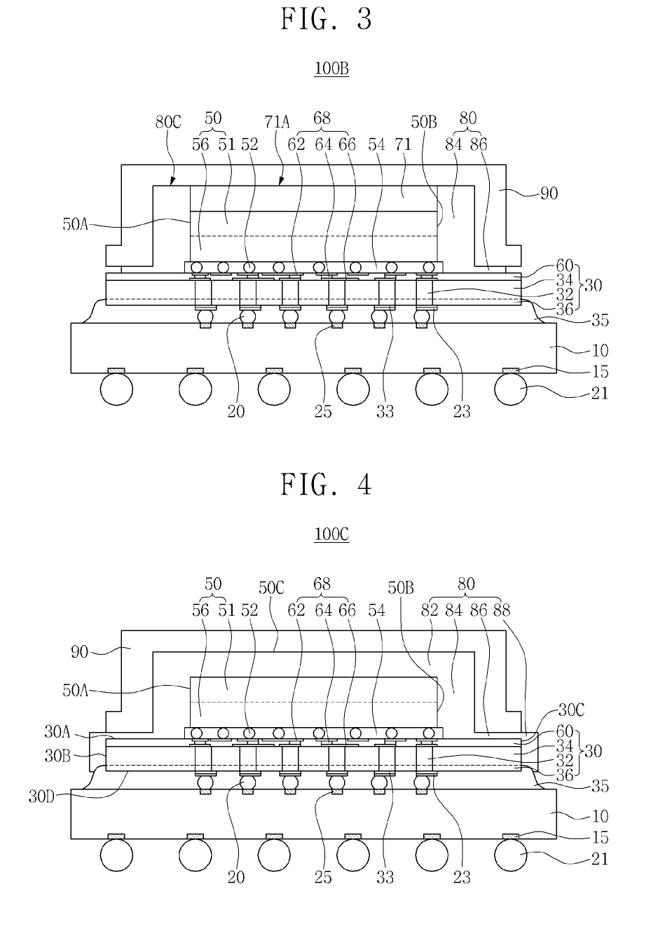

FIG. 3 is a cross-sectional view of a semiconductor package 100B according to embodiments of the inventive concepts.

Referring to FIG. 3, the TIM layer 80 may be formed at a higher level than the second semiconductor chip 50. The TIM layer 80 may surround side surfaces 50A, 50B of a second semiconductor chip 50. A first encapsulant 71 may be formed between the second semiconductor chip 50 and the heat spreader 90. A top surface 71A of the first encapsulant 71 may be at the same level as a top surface 80C of the TIM layer 80. A heat spreader 90 may be adhered to the top surfaces 71A, 80C, respectively, of the first encapsulant 71 and the TIM layer 80. The first encapsulant 71 may, for instance, include an epoxy molding compound (EMC).

FIG. 4 is a cross-sectional view of a semiconductor package 100C according to further embodiments of the inventive concepts.

Referring to FIG. 4, a TIM layer 80 may be arranged on a top surface 30A of the first semiconductor chip 30. The TIM layer 80 may also cover side surfaces 30B, 30C of the first semiconductor chip 30. Although not shown, the TIM layer 80 may further be formed on a bottom surface 30D of the first semiconductor chip 30. The TIM layer 80 may cover a top surface 50C of the second semiconductor chip 50. The TIM layer 80 may cover side surfaces 50A, 50B of the second semiconductor chip 50. The TIM layer 80 may be integrally formed to cover the first semiconductor chip 30 and the second semiconductor chip 50. The TIM layer 80 may include an upper portion 82, first side portions 84, lower portions 86, and second side portions 88. The upper portion 82 of the TIM layer 80 may be formed between the heat spreader 90 and the second semiconductor chip 50. The first side portions 84 of the TIM layer 80 may be formed between the side surfaces 50A, 50B of the second semiconductor chip 50 and side surfaces of the heat spreader 90. The lower portions 86 of the TIM layer 80 may be formed between the top surface 30A of the first semiconductor chip 30 and bottom surfaces of the heat spreader 90. Second side portions 88 of the TIM layer 80 may be in contact with the side surfaces 30B, 30C of the first semiconductor chip 30. The second side portions 88 of the TIM layer 80 may be exposed outside of the semiconductor package. An upper portion may refer to a substantially flat portion formed in an upper layer of the TIM layer 80. A side portion may refer to a substantially flat portion forming a side surface of the TIM layer 80. A lower portion may refer to a substantially flat portion formed in a lower layer of the TIM layer 80. A first side portion may refer to a side portion that is configured to connect the upper portion and the lower portion, and a second side portion may refer to a side portion extending downward from the lower portion.

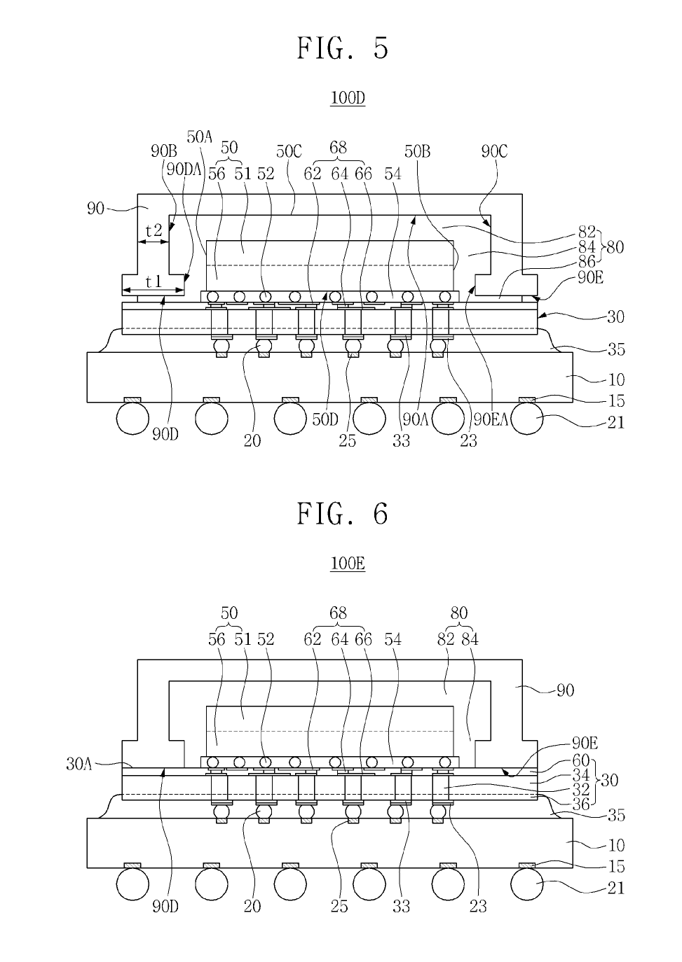

FIG. 5 is a cross-sectional view of a semiconductor plate 100D according to still further embodiments of the inventive concepts.

Referring to FIG. 5, a heat spreader 90 may include a top surface 90A and side surfaces 90B, 90C extending from the top surface. The side surfaces 90B, 90C of the heat spreader 90 may extend along side surfaces 50A, 50B of the second semiconductor chip 50. Bottom surfaces 90D, 90E of the extending side surfaces of the heat spreader 90 may be formed at a lower level than a bottom surface 50D of the second semiconductor chip 50. The bottom surfaces 90D, 90E of the heat spreader 90 may have a width t2 that is greater than a width t1 of side portions of the heat spreader 90 corresponding to the side surfaces 50A, 50B. Side surfaces 90DA, 90EA of bottom portions of the heat spreader 90, corresponding to the bottom surfaces 90D, 90E, may be formed closer to the side surfaces 50A, 50B of the second semiconductor chip 50 than to the side surfaces 90B, 90C, respectively, of the heat spreader 90. The bottom surfaces 90D, 90E of the heat spreader 90 may extend outside the second semiconductor chip 50. Each of the combined side and bottom portions of the heat spreader 90 may have an inverted T shape when viewed in cross-section. The width t1 of the bottom surfaces 90D, 90E of the heat spreader 90 may be increased to increase a contact area between the bottom surfaces 90D, 90E of the heat spreader 90 and the lower portions 86 of the TIM layer 80.

FIG. 6 is a cross-sectional view of a semiconductor package 100E according to additional embodiments of the inventive concepts.

Referring to FIG. 6, bottom surfaces 90D, 90E of a heat spreader 90 may be in contact with a top surface 30A of a first semiconductor chip 30. The first semiconductor chip 30 may include a logic element. A hot spot (not shown) of the first semiconductor chip 30 may be a logic element. The heat spreader 90 may be adhered to the hot spot of the first semiconductor chip 30 to increase heat dissipation efficiency.

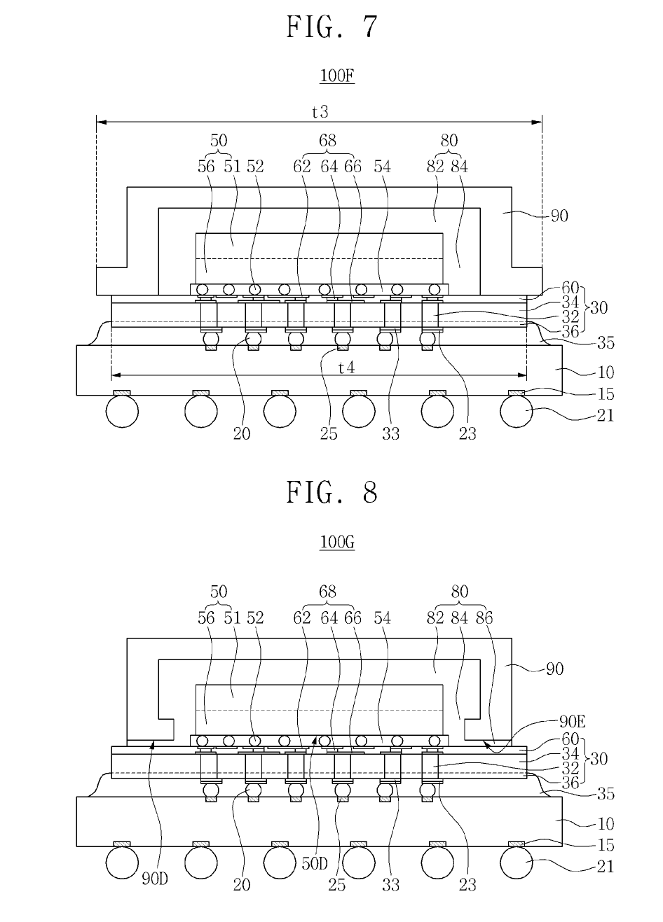

FIG. 7 is a cross-sectional view of a semiconductor package 100F according to still other embodiments of the inventive concepts.

Referring to FIG. 7, a heat spreader 90 of the semiconductor package 100F according to these embodiments of the inventive concepts may be formed on a first semiconductor chip 30 and may completely cover a second semiconductor chip 50. The heat spreader 90 may have a greater width than that of the first semiconductor chip 30 (t3>t4). In this case, t3 refers to the width of the heat spreader 90 in the semiconductor package 100F, and t4 refers to the width of the first semiconductor chip 30. Since the heat spreader 90 has a greater width than the first semiconductor chip 30, the heat spreader 90 may protect the first semiconductor chip 30 from external stress.

An air layer (not shown) may be formed between the heat spreader 90 and top, side, and bottom surfaces of the second semiconductor chip 50. A TIM layer 80 may fill in the air layer.

FIG. 8 is a cross-sectional view of a semiconductor package 100G according to more embodiments of the inventive concepts.

Referring to FIG. 8, in the semiconductor package 100G one or more bottom surfaces 90D, 90E of a heat spreader 90 may extend inward toward a second semiconductor chip 50. The bottom surface of the heat spreader 90 may be formed at a lower level than a bottom surface 50D of the second semiconductor chip 50. Since the bottom surfaces 90D, 90E of the heat spreader 90 have a greater thickness than side portions of the heat spreader 90, a bottom surface area is increased and heat dissipation efficiency may be improved. Thus, the heat spreader 90 may serve as an effective heat dissipation unit for the semiconductor package 100G including hot spots formed in first semiconductor chip 30.

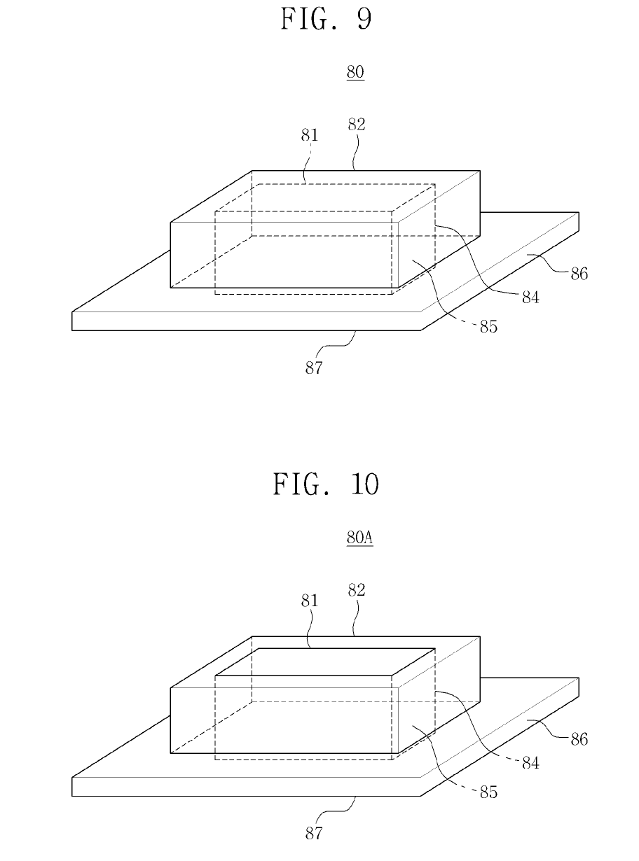

FIG. 9 is a perspective view of one configuration of a TIM layer 80 that may provide an upper layer of a semiconductor package according to embodiments of the inventive concepts.

Referring to FIG. 9, the TIM layer 80 may include an upper portion 82, side portions 84 extending from the upper portion 82, and lower portions 86 extending from the side portions 84. A cavity 81 into which a second semiconductor package 50 may be inserted may be formed in the TIM layer 80. The cavity 81 of the TIM layer 80 may receive a semiconductor chip 50 (see, e.g., FIG. 1) such that top and side surfaces 50C, 50A, 50B of the second semiconductor chip 50 contact the TIM layer 80. The cavity 81 of the TIM layer 80 may also receive a first contact layer 54 that connects the second semiconductor chip 50 with a first semiconductor chip 30.

First bumps 20 may be protected by the first contact layer 54. The lower portions 86 of the TIM layer 80 may have substantially planar bottom surfaces. Heat generated by the first semiconductor chip 30 may be transmitted through the lower portions 86 of the TIM layer 80 to the heat spreader 90. The TIM layer 80 may, for example, include aluminum or zirconia, which is highly thermally conductive. Alumina and zirconia may be ground into fine particles, suspended in a thermosetting resin, and stacked on the first semiconductor chip 30. The TIM layer 80 may be formed using a printing process, such as a spin coating process or an inkjet printing process. Since a suspension surrounding the ceramic particles have a good adhesive property, the suspension may be adhered to the first semiconductor chip 30 during a curing process. The TIM layer 80 may be coated at room temperature and thermally cured to form a lower portion adhesion unit 87, a side portion adhesion unit 85, and an upper portion adhesion unit 81. When an amount of a thermosetting resin serving as a curing agent increases, the adhesive property of the TIM layer 80 may also increase. The TIM layer 80 may be stacked on the first semiconductor chip 30 or the second semiconductor chip 50. The spin coating process and the printing process may each exhibit good dispersibility characteristics.

When the amount of thermosetting resin increases, coherence of the TIM layer 80 with respective surfaces of the heat spreader 90 or the second semiconductor chip 50 may increase, but heat dissipation efficiency may be degraded. When the amount of thermosetting resin is reduced, heat dissipation efficiency may increase, but pores may be formed and coherence of the TIM layer 80 with the second semiconductor chip 50 or the first semiconductor chip 30 may be degraded.

When the ceramic particles have a fine size, pores may not be formed, or are less likely to be formed, between a top surface of the first semiconductor chip 30 and the TIM layer 80, and between top and side surfaces of the second semiconductor chip 50 and the TIM layer 80, during the curing of the suspension. Heat generated by the first semiconductor chip 30 and the second semiconductor chip 50 may thereby be effectively emitted.

FIG. 10 is a perspective view of a configuration of a TIM layer 80A according to other embodiments of the inventive concepts.

Referring to FIG. 10, the TIM layer 80A may include side portions 84 and lower portions 86 extending from the side portions 84. A cavity 81 may be formed in the center of the TIM layer 80A to expose a top surface 50C of a second semiconductor package 50 (see, e.g., FIG. 2). The TIM layer 80A may have substantially the same height as the second semiconductor chip 50. A top surface of the TIM layer 80A may form a substantially planar surface with a top surface of the second semiconductor chip 50. A heat spreader 90 having a substantially planar surface may be adhered to the top surfaces of the TIM layer 80A and the second semiconductor chip 50.

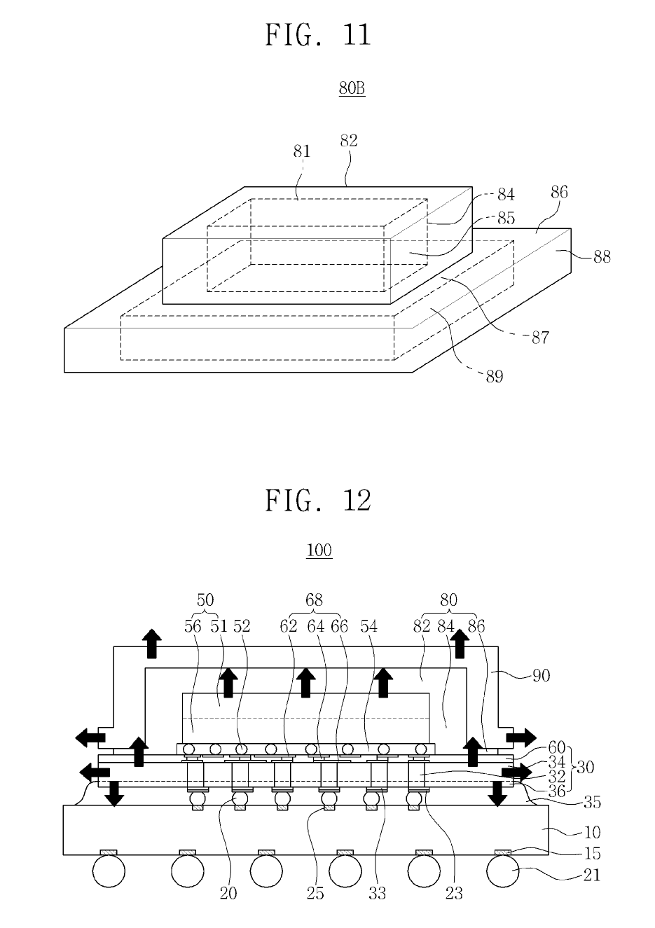

FIG. 11 is a perspective view of a configuration of a TIM layer 80B according to other embodiments of the inventive concepts.

Referring to FIG. 11, the TIM layer 80B may include an upper portion 82, first side portions 84 extending from the upper portion 82, lower portions 86 extending from the first side portions 84, and second side portions 88 extending from the lower portions 86. The first side portions 84 may be in contact with side surfaces of a second semiconductor chip 50, and the second side portions 88 may be in contact with side surfaces of a first semiconductor chip 30. The TIM layer 80B may be in direct contact with the first and second semiconductor chips 30 and 50 so that heat generated by the first and second semiconductor chips 30 and 50 can be externally emitted. The upper portion 82, the first and second side portions 84 and 88, respectively, and the lower portions 86 of the TIM layer 80B may be integrally formed. Since the TIM layer 80B may contain a thermosetting resin and ceramic particles, the shape of TIM layer 80B may be freely deformed during a fabrication process. Since the first semiconductor chip 30 and the second semiconductor chip 50 included in a semiconductor package 100 are covered by the thermosetting resin, the outside of the semiconductor package 100 may be protected from external stress. Since the TIM layer 80B may be cured after it is combined with the first and second semiconductor chips 30 and 50 and the heat spreader 90, the TIM layer 80B may be highly coherent with the first and second semiconductor chips 30 and 50 and the heat spreader 90.

FIG. 12 is a schematic diagram showing the flow of heat in a semiconductor package according to embodiments of the inventive concepts.

Referring to FIG. 12, heat generated by a first semiconductor chip 30 and a second semiconductor chip 50 may be transmitted in the directions indicated by the arrows. Heat generated by the second semiconductor chip 50 may be transmitted through the TIM layer 80 to the heat spreader 90. Heat transmitted to the heat spreader 90 may be externally emitted.

Heat generated by the first semiconductor chip 30 may be transmitted to lower portions 86 of a TIM layer 80. Heat transmitted to the lower portions 86 of the TIM layer 80 may be transmitted to a heat spreader 90, which is adhered to the TIM layer 80. Heat generated by the first semiconductor chip 30 may be emitted directly to the outside through side surfaces of the first semiconductor chip 30.

Since the heat spreader 90 includes a highly thermally conductive metal, the entire heat spreader 90 may be heated due to rapid thermal conduction. The heat spreader 90 may have a large heat radiation area and may emit heat to the outside. Heat emitted by the first semiconductor chip 30 may also be transmitted downward from the first semiconductor chip 30.

Heat transmitted downward from the first semiconductor chip 30 may heat an underfill 35. Heat transmitted to the underfill 35 may then be transmitted to a substrate 10 having a high CTE. The heat heating the underfill 35 may heat lower connection terminals 33 of TSVs 32. Heat generated by the underfill 35 may be transmitted to the substrate 10 and the first semiconductor chip 30.

The underfill 35 may have a middle CTE between CTEs of the substrate 10 and the first semiconductor chip 30. Damage to the first semiconductor chip 30 may be prevented by transmitting heat from the first semiconductor chip 30. Shear stress may not be applied to the first bumps 20.

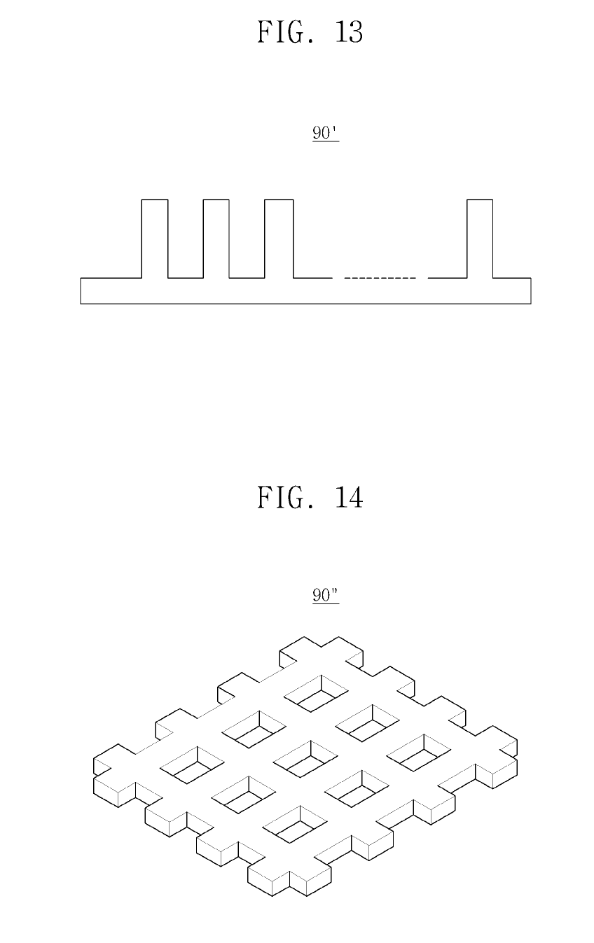

FIG. 13 is a diagram of a configuration of a heat spreader 90A in a semiconductor package according to embodiments of the inventive concepts.

Referring to FIG. 13, the heat spreader 90′ may be in contact with a TIM layer 80 (see, e.g., FIG. 1). Various kinds of rough surface characteristics may be provided in a top surface of the heat spreader 90′ to increase the surface area of the top surface of the heat spreader 90′. As shown in FIG. 13, this may include fins or ridges formed along an upper surface of the heat spreader 90A.

Referring to FIG. 14, a heat spreader 90″ according to another embodiment may include a structure having a lattice shape or a mesh shape.

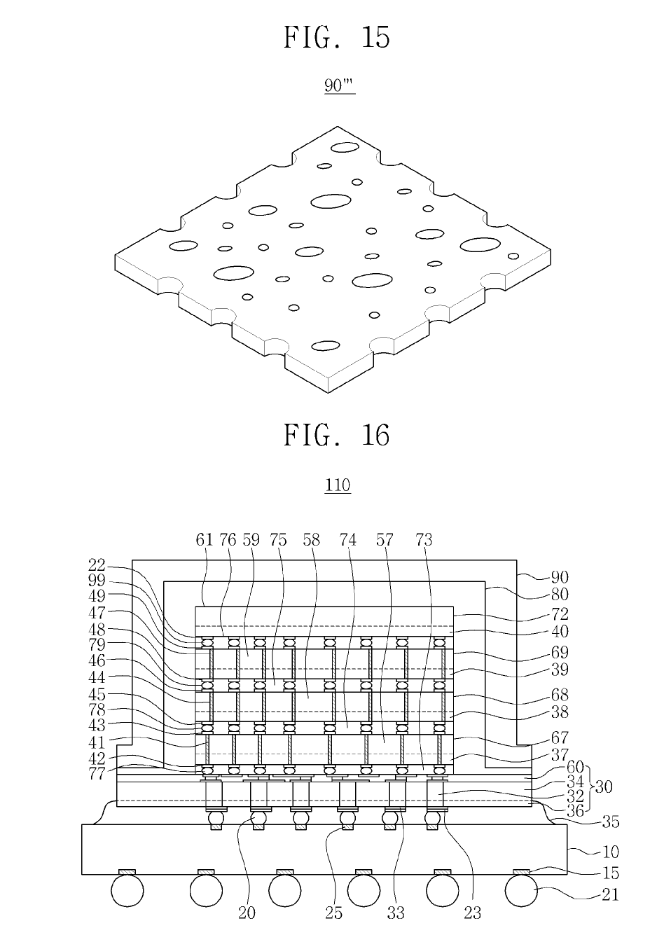

Referring to FIG. 15, a heat spreader 90′″ according to a still further embodiment may include a porous material layer.

FIG. 16 is a cross-sectional view of a configuration of an MCP 110 according to embodiments of the inventive concepts.

Referring to FIG. 16, the MCP 110 may include a substrate 10 having a first semiconductor chip 30 mounted on the substrate 10 and having TSVs 32. A redistribution layer 60 may be formed on the first semiconductor chip 30. Third through sixth semiconductor chips 57, 58, 59, and 61, respectively, may be sequentially mounted on the redistribution layer 60. A TIM layer 80 may be formed to cover a top surface of the redistribution layer 60 and side surfaces of the third through sixth semiconductor chips 57, 58, 59, and 61, respectively, along with a top surface of the topmost semiconductor chip 61. A heat spreader 90 may be arranged to cover the TIM layer 80.

The substrate 10 may include a plurality of lower lines, first upper lands 25, and first lower lands 15. The first semiconductor chip 30 may include a first semiconductor layer 34, a redistribution layer 60, first bumps 20, and TSVs 32. First bumps 20 may be formed between first upper lands 25 of the substrate 10 and lower connection terminals 33 of the first semiconductor chip 30. An underfill 35 may be formed between the substrate 10 and the first semiconductor chip 30. The underfill 35 may be filled between the first bumps 20 that are electrically connected to the first semiconductor chip 30.

The third semiconductor chip 57 may include a third semiconductor layer 67, second TSVs 41, a second upper electrode 43, and a second lower electrode 42. The third semiconductor layer 67 may include a semiconductor wafer. The semiconductor wafer may, for instance, include a Group-IV material or a Group III-V compound. For example, the third semiconductor layer 67 may include silicon (Si), germanium (Ge), or a gallium arsenide (GaAs). A second contact layer 73 may be formed between the third semiconductor chip 57 and the redistribution layer 60.

The second contact layer 73 may include third connection terminals 77. Each of the third connection terminals 77 may include a micro-bump. The second contact layer 73 may include a DAF.

The third semiconductor layer 67 may include one or more third circuit elements 37. The third circuit elements 37 may be memory chips, such as a volatile memory or a nonvolatile memory. For example, each of the third circuit elements 37 may include a mobile DRAM.

The fourth semiconductor chip 58 may include a fourth semiconductor layer 68, third TSVs 44, a third upper electrode 46, and a third lower electrode 45. The fourth semiconductor layer 68 may include a semiconductor wafer. The semiconductor wafer may, for instance, include a Group-IV material or a Group III-V compound. For example, the fourth semiconductor layer 68 may include silicon (Si), germanium (Ge), or a gallium arsenide (GaAs). The third contact layer 74 may be formed between the fourth semiconductor chip 58 and the third semiconductor chip 57.

The third contact layer 74 may include fourth contact terminals 78. Each of the fourth contact terminals 78 may include a micro-bump. The third contact layer 74 may include a DAF.

The fourth semiconductor layer 68 may include one or more fourth circuit elements 38. The fourth circuit elements 38 may be memory chips, such as a volatile memory or a nonvolatile memory. For example, each of the fourth circuit elements 38 may include a mobile DRAM.

The fifth semiconductor chip 59 may include a fifth semiconductor layer 69, fourth TSVs 47, a fourth upper electrode 49, and a fourth lower electrode 48. The fifth semiconductor layer 69 may include a semiconductor wafer. The semiconductor wafer may, for instance, include a Group-IV material or a Group III-V compound. For example, the fifth semiconductor layer 69 may include silicon (Si), germanium (Ge), or a gallium arsenide (GaAs). The fourth contact layer 75 may be formed between the fifth semiconductor chip 59 and the fourth semiconductor chip 58.

The fourth contact layer 75 may include fifth connection terminals 79. Each of the fifth connection terminals 79 may include a micro-bump. The fourth contact layer 75 may include a DAF.

The fifth semiconductor layer 69 may include one or more fifth circuit elements 39. The fifth circuit elements 39 may be memory chips, such as a volatile memory or a nonvolatile memory. For example, each of the fifth circuit elements 39 may include a mobile DRAM.

The sixth semiconductor chip 61 may include a sixth semiconductor layer 72 and a sixth lower electrode 22. The sixth semiconductor layer 72 may include a semiconductor wafer. For example, the sixth semiconductor layer 72 may include silicon (Si), germanium (Ge), or a gallium arsenide (GaAs). The fifth contact layer 76 may be formed between the sixth semiconductor chip 61 and the fifth semiconductor chip 59.

The fifth contact layer 76 may include sixth connection terminals 99. Each of the sixth connection terminals 99 may include a micro-bump. The fifth contact layer 76 may include a DAF.

The sixth semiconductor layer 72 may include one or more sixth circuit elements 40. The sixth circuit elements 40 may be memory chips, such as a volatile memory or a nonvolatile memory. For example, each of the sixth circuit elements 40 may include a mobile DRAM.

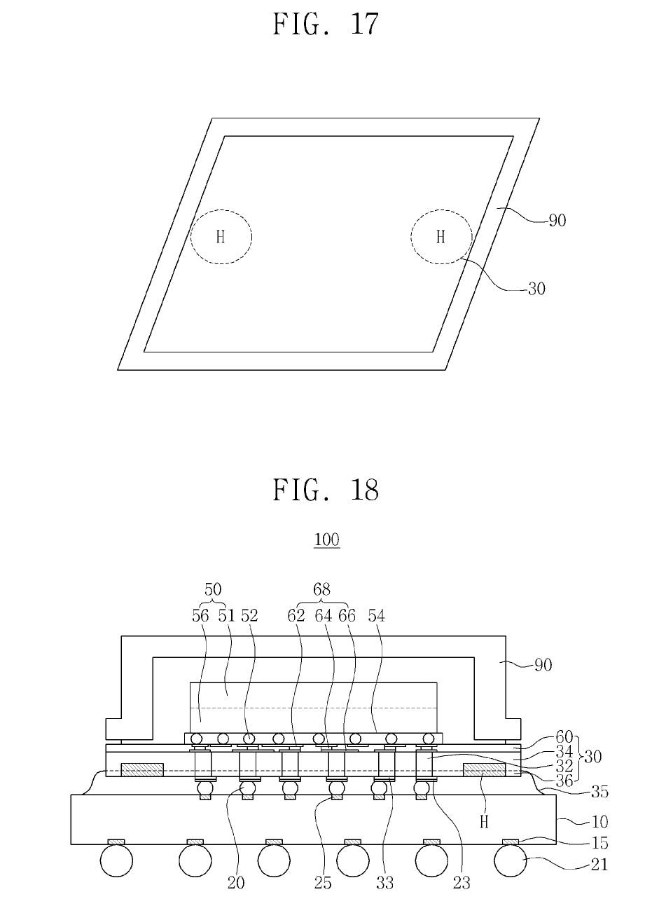

FIG. 17 is a plan view of a configuration of a first semiconductor chip 30 having hot spots in an MCP according to other embodiments of the inventive concepts.

Referring to FIG. 17, the first semiconductor chip 30 may include a logic chip and a central processing unit (CPU). A graphic processing unit (GPU) may be formed on an edge of the logic chip. With a growing interest in multimedia content and PC games, graphic cards have become heavily relied upon. For example, processors for graphics-related operations have been needed to embody 3-dimensional functions. A unit configured to enhance a graphic function may be the GPU arranged on the logic chip. The logic chip may therefore include hot spots H. When a temperature of the hot spots H is not controlled, generation of heat caused by a high clock rate of the logic chip and an increase in the integration density of transistors cannot corrected for. Similarly, the GPU may be fabricated using a finer process, and may process graphics at a higher speed because the number of transistors included in each semiconductor chip may be increased. As described above, a rise in the number of transistors and an increase in the integration density of the transistors may cause excessive generation of heat. To prevent the excessive generation of heat, a clock rate, a voltage, or a capacitance may be controlled. However, when the clock rate, the voltage, or the capacitance are controlled, performance may be degraded, and a semiconductor package may not be able to properly fulfill a multi-function design characteristic.

To overcome these drawbacks, a method of controlling heat generated by the first semiconductor chip 30 may be considered. A TIM layer 80 may be installed in communication with a hot spot of the first semiconductor chip 30. A heat spreader 90 may be installed on the TIM layer 80. The heat spreader 90 may be arranged on the opposite side of a spot contacted by the TIM layer 80 and may have a large heat dissipation area. Due to high heat-generation during chip performance, the first semiconductor chip 30 may otherwise be damaged due to accumulation of heat in the first semiconductor chip 30. Furthermore, as described above, the first semiconductor chip 30 may be damaged due to a disparity in CTE between the substrate 10 and the first bumps 20, which may surround the periphery of the first semiconductor chip 30.

In a semiconductor package according to embodiments of the inventive concepts, when a hot spot H is disposed on an edge of a logic chip corresponding to the first semiconductor chip 30 as shown in FIG. 17, the heat spreader 90 may serve as an effective heat dissipation unit.

FIG. 18 is a cross-sectional view of configuration of a semiconductor package including a GPU and a CPU according to embodiments of the inventive concepts.

Referring to FIG. 18, a semiconductor package 100 may include a substrate 10, a first semiconductor chip 30 mounted on the substrate 10 and having hot spots H, a redistribution layer 60 disposed and electrically connected to the first semiconductor chip 30, a second semiconductor chip 50 electrically connected to redistribution lands 62 of the redistribution layer 60, a TIM layer 80 configured to surround a top surface of the first semiconductor chip 30 and side and top surfaces of the second semiconductor chip 50, and a heat spreader 90 covering the TIM layer 80.

As shown in FIG. 18, each of the hot spots H may be formed in a peripheral portion of the first semiconductor chip 30. A first lower portion 86 of the TIM layer 80 may be formed over the hot spots H. A heat spreader 90 may be arranged on a top surface of the first lower portion 86.

Heat generated by the hot spots H may be transmitted to the TIM layer 80 and then transmitted to the heat spreader 90. The first semiconductor chip 30 may be formed of silicon and the underfill 35 may have a middle CTE between CTEs of the first semiconductor chip 30 and the substrate 10, so that structural stability may be ensured.

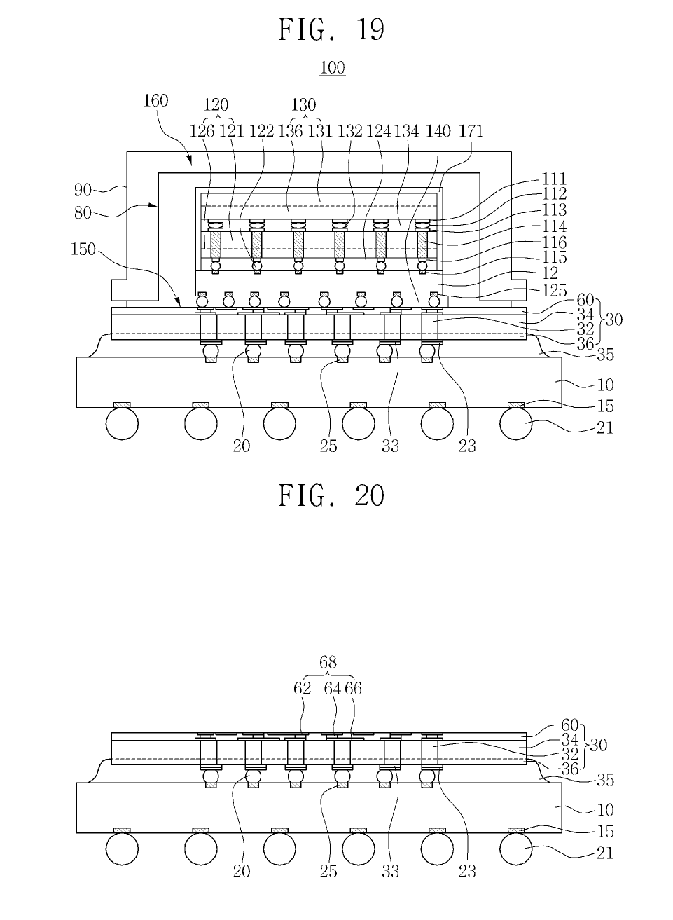

FIG. 19 is a cross-sectional view of a semiconductor package according to further embodiments of the inventive concepts.

Referring to FIG. 19, a first package 150, in which a first semiconductor chip 30 is mounted, may be formed on a substrate. A second package 160, in which seventh and eighth semiconductor chips 120 and 130 are mounted, may be formed on the first package 150. The first package 150 may include a redistribution layer 60 to adjust a pitch between the first package 150 and the second package 160. The seventh semiconductor chip 120 and the eighth semiconductor chip 130, which may be mounted on the package substrate 12, may be mounted on the redistribution layer 60.

The eighth semiconductor chip 130 may be electrically connected to the package substrate 12 through a fifth TSV 114 of the seventh semiconductor chip 120. The package substrate 12 may be a substrate including a plurality of lower lines. The package substrate 12 may, for example, include a rigid PCB, a flexible PCB, or a rigid-flexible PCB. The package substrate 12 may include second upper lands 115 and second lower lands 125.

The seventh semiconductor chip 120 may include a plurality of TSVs 114, a seventh upper electrode 113, a seventh lower electrode 116, and a seventh semiconductor layer 121. The seventh semiconductor layer 121 may include a semiconductor wafer. For example, the seventh semiconductor layer 121 may include silicon (Si), germanium (Ge), or gallium arsenide (GaAs). A sixth adhesive layer 124 may be formed between the package substrate 12 and the seventh semiconductor chip 120.

The sixth adhesive layer 124 may include sixth connection terminals 122. Each of the sixth connection terminals 122 may include a micro-bump. The sixth adhesive layer 124 may include a DAF.

The seventh semiconductor layer 121 may include a seventh circuit element 126. The seventh circuit element 126 may be a memory chip, such as a volatile memory or a nonvolatile memory. For example, the seventh circuit element 126 may include a mobile DRAM.

The eighth semiconductor chip 130 may include an eighth semiconductor layer 131 and an eighth lower electrode 111. The eighth semiconductor layer 131 may include a semiconductor wafer. For instance, the eighth semiconductor layer 131 may include silicon (Si), germanium (Ge), or a gallium arsenide (GaAs). A seventh contact layer 134 may be formed between the seventh semiconductor chip 120 and the eighth semiconductor chip 130.

The seventh contact layer 134 may include seventh connection terminals 112. Each of the seventh connection terminals 112 may include a micro-bump. The seventh contact layer 134 may include a DAF.

The eighth semiconductor layer 131 may include one or more eighth circuit elements 136. The eighth circuit elements 136 may be memory chips, such as a volatile memory or a nonvolatile memory. For example, each of the eighth circuit elements 136 may include a mobile DRAM.

Since the first package 150 may have generally the same configuration as the previously-described first semiconductor chip 30, a detailed description thereof is omitted.

The second package 160 may be electrically connected to the first package 150 through an eighth contact layer 140 disposed on a redistribution layer 60. The eighth contact layer 140 may include a DAF.

The second package 160 may be surrounded with a second encapsulant 171. The second encapsulant 171 may be surrounded with a TIM layer 80. A heat spreader 90 may be arranged outside the TIM layer 80 to enhance structural stability.

FIGS. 20 through 26 are cross-sectional views of a semiconductor package during various stages of fabrication, illustrating a method of fabricating a semiconductor package according to embodiments of the inventive concepts.

More particularly, FIGS. 20 through 22 illustrate a process of adhering a second semiconductor chip 50 after forming an underfill 35 between the first semiconductor chip 30 and the substrate 10 in the method of fabricating the semiconductor package.

Referring to FIG. 20, the first semiconductor chip 30 may be electrically connected to the substrate 10 using first bumps 20. The first semiconductor chip 30 may include the first semiconductor layer 34 and the redistribution layer 60.

A first circuit element 36 may be formed in the first semiconductor layer 34. The first circuit element 36 may be an active region in the semiconductor package 100. Although the first circuit element 36 is shown formed in a lower portion of the semiconductor layer 34, the first circuit element 36 may be formed in an upper portion of the semiconductor layer 34 near the redistribution layer 60.

An insulating layer and lower connection terminals 33 may be formed on a bottom surface of the first circuit element 36. At least some of the lower connection terminals 33 may be electrically connected to the TSVs 32. At least some of the lower connection terminals 33 may be connected to an active region of the first semiconductor layer 34. First bumps 20 may be formed under the lower connection terminals 33. The lower connection terminals 33 may protrude outward from the semiconductor layer 34. The TSVs 32 may penetrate the first semiconductor layer 34. The TSVs 32 may electrically connect the TSV pad 66 with the lower connection terminal 33. The TSV pad 66 may protrude outside the semiconductor layer 34. An underfill 35 may be filled to surround the first bumps 20. The underfill 35 may have a middle CTE between CTEs of the substrate 10 and the semiconductor chip 30.

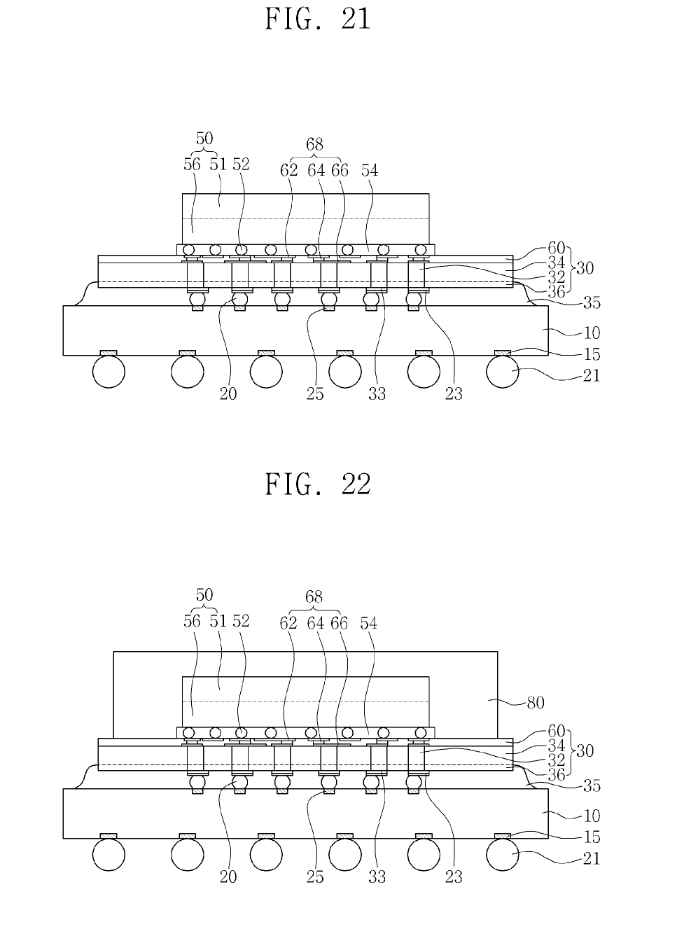

Referring to FIG. 21, a second semiconductor chip 50 may be mounted on the first semiconductor chip 30 that is disposed on and electrically connected to the substrate 10. The second semiconductor chip 50 may be mounted on the first semiconductor chip 30 through second bumps 52 using a flip-chip process. A first contact layer 54 may be formed between the first semiconductor chip 30 and the second semiconductor chip 50. The first contact layer 54 may include a DAF or a non-conductive material (NCF).

Second bumps 52 may be formed through the first contact layer 54 and may electrically connect a second semiconductor layer 51 with the redistribution layer 60.

The first contact layer 54 may include a tape-type material layer, a liquid coating curable material layer, or a combination thereof. The first contact layer 54 may include a thermosetting structure, a thermal plastic, a UV curable material, or a combination thereof. The first contact layer 54 may include an epoxy-based curing agent, a silicon-based curing agent, a phenol-type curing agent, an amine-type curing agent, an acrylic polymer, or a combination thereof.

Referring to FIG. 22, a method of fabricating a semiconductor package according to embodiments of the inventive concepts may include forming a TIM layer 80 on a top surface of the semiconductor chip 30 and a top surface of the second semiconductor chip 50. The TIM layer 80 may be coated on side surfaces of the second semiconductor chip 50 and side surfaces of the first contact layer 54. The coating of the TIM layer 80 may include suspending thermally conductive particles containing alumina in a thermosetting resin. The suspension may be coated as a liquid type on the top surfaces of the first semiconductor chip 30 and the second semiconductor chip 50. Since the suspension containing thermally conductive particles forms a liquid, the suspension may be coated on the top and side surfaces of the second semiconductor chip 50 due to the dead weight thereof. The suspension may be uniformly coated between the second semiconductor chip 50 and the first contact layer 54. The suspension may, for instance, be coated using a spin coating process or an inkjet printing process. Alternatively, the suspension may be laminated by passing the semiconductor package 100 on which the second semiconductor chip 50 is stacked, between upper and lower rollers, and spraying a suspension on the surface of the second semiconductor chip 50.

The above-described suspension containing thermally conductive particles may be cured to harden the TIM layer 80. The TIM layer 80 may be adhered to top and side surfaces of the first semiconductor chip 30 and the second semiconductor chip 50 and side surfaces of the first contact layer 54.

Referring back to FIG. 1, the semiconductor package 100 according to the embodiments of the inventive concepts may include a first semiconductor chip 30 and a second semiconductor chip 50. As shown in FIG. 21, the second semiconductor chip 50 may be adhered onto the first semiconductor chip 30, and a heat spreader 90 may be adhered onto a TIM layer 80. Since the TIM layer 80 is in a suspended state, the TIM layer 80 may have a moldable shape. Since the heat spreader 90 includes a metallic element, the heat spreader 90 may be pressed against and adhered to the TIM layer 80 as shown in FIG. 1. When the heat spreader 90 is bonded under pressure to the TIM layer 80, coherence of the heat spreader 90 with the TIM layer 80 may be enhanced. An upper plate 82, side plates 84, and lower plates 86 of the TIM layer 80 may be formed during the curing of the TIM layer 80. The heat spreader 90 may be adhered to the TIM layer 80 to ensure structural stability of the semiconductor package 100.

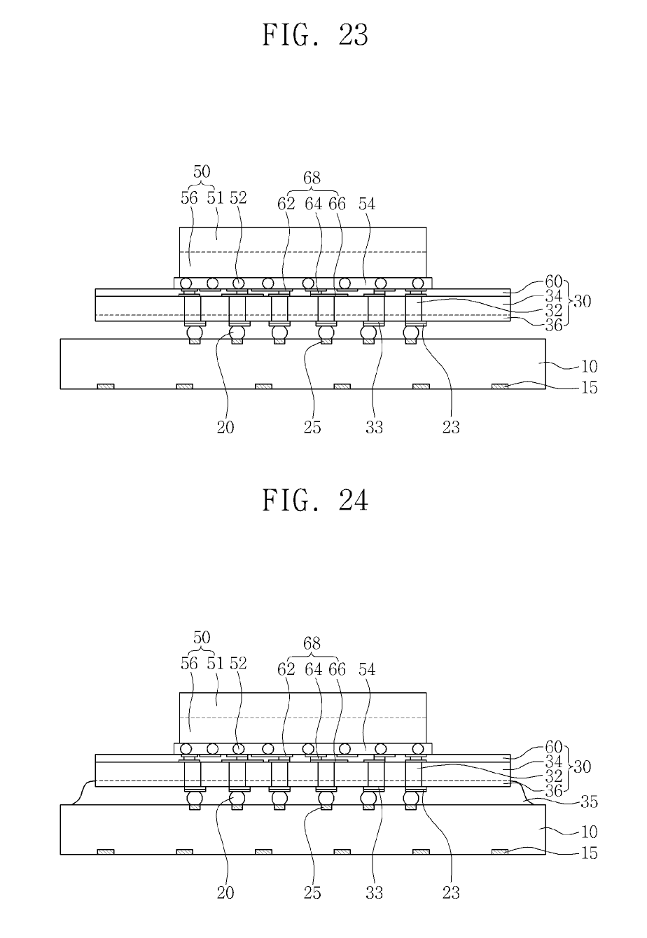

FIGS. 23 through 26 illustrate a process of forming an underfill 35 between the first semiconductor chip 30 and the substrate 10 after adhering a semiconductor chip 50 to a first semiconductor chip 30 in a method of fabricating a semiconductor package. External connection terminals 21 (see FIG. 1) may be omitted. First lower lands 15 of a semiconductor package 100 may be exposed. The lower lands 15 may include conductive tabs, finger electrodes, lead grid arrays (LGAs), pin grid arrays (PGAs), or a combination thereof.

Referring to FIG. 23, the second semiconductor chip 50 may be adhered to the first semiconductor chip 30 having a redistribution layer 60 using a first contact layer 54. Second bumps 52 may be formed in the first contact layer 54 and may electrically connect the second semiconductor chip 50 with the redistribution layer 60 formed on the first semiconductor chip 30. The second bumps 52 may be adhered to the second semiconductor chip 50 using a flip-chip bonding process. The second bumps 52 may be micro-bumps. Although the process of adhering the second semiconductor chip 50 to the first semiconductor chip 30 is described above, before the second semiconductor chip 50 is adhered to the first semiconductor chip 30, the substrate 10 may be adhered to the first semiconductor chip 30. The process of adhering the first semiconductor chip 30 to the substrate 10 may be performed after the process of adhering the first semiconductor chip 30 to the second semiconductor chip 50.

The first contact layer 54 may be adhered to the second semiconductor chip 50 and the redistribution layer 60 of the first semiconductor chip 30 using a thermal curing process

Referring to FIG. 24, an underfill 35 may be formed to surround first bumps 20. The underfill 35 may include epoxy, BCB, or PI. A CTE of the underfill 35 may vary according to the content of epoxy. Thermal stress generated by the first semiconductor chip 30 may be reduced or eliminated by controlling the CTE of the underfill 35. The underfill 35 may partially cover side surfaces of the first semiconductor layer 34.

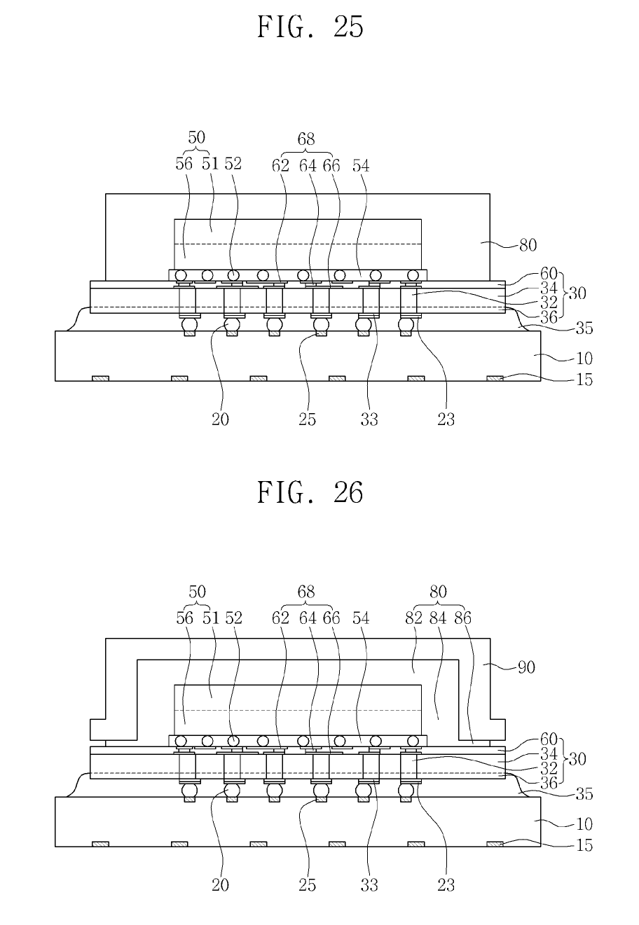

Referring to FIG. 25, a TIM layer 80 may be coated on the semiconductor package 100 having the underfill 35. The TIM layer 80 may be obtained by suspending ceramic particles, such as alumina or zirconia, in a thermosetting resin. The TIM layer 80 may, for example, be coated using a spin coating process or an inkjet printing process.

Referring to FIG. 26, a heat spreader 90 may be adhered onto the semiconductor package 100 to which the TIM layer 80 is adhered. Heat radiation efficiency of the first semiconductor chip 30 may be increased using the heat spreader 90 adhered to the TIM layer 80.

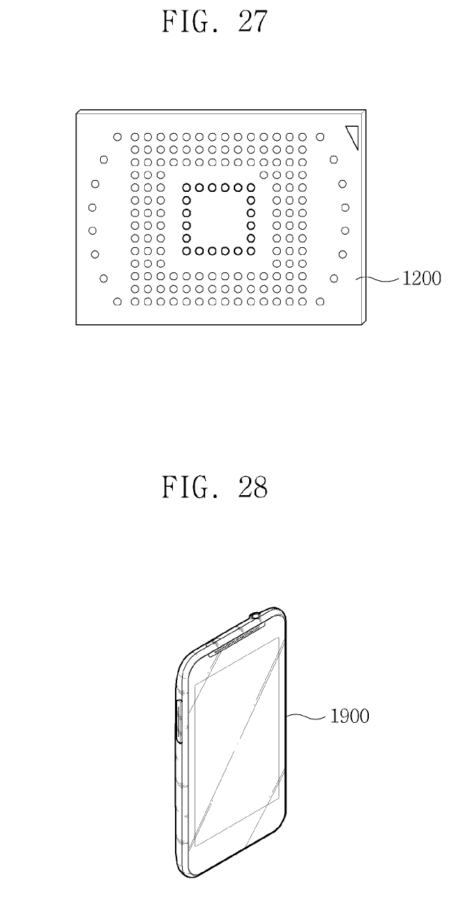

FIGS. 27 through 29 are perspective views of various electronic devices according to embodiments of the inventive concepts.

Referring to FIGS. 27 through 29, a semiconductor package described with reference to FIGS. 1 through 26 may be applied to an electronic system 2100, such as an embedded multi-media chip (eMMC) 1200, a smartphone 1900, a netbook, a laptop computer, or a tablet personal computer (tablet PC). For example, a semiconductor package similar to those described with reference to FIGS. 1 through 26 may be mounted on a mainboard of the smartphone 1900.

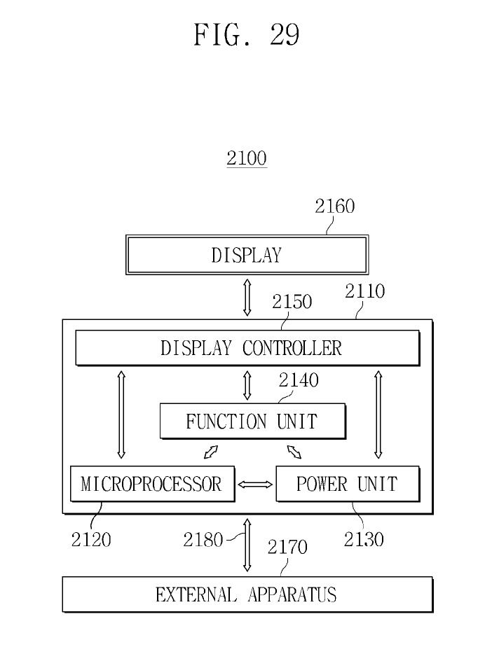

Referring to FIG. 29, a semiconductor package similar to those described above with reference to FIGS. 1 through 26 may be applied to an electronic system 2100. The electronic system 2100 may include a body 2110, a microprocessor (MP) 2120, a power unit 2130, a function unit 2140, and a display controller 2150. The body 2110 may be a mother board having a PCB. The MP 2120, the power unit 2130, the function unit 2140, and the display controller 2150 may be mounted on the body 2110. A display 2160 may be disposed inside or outside the body 2110. For example, the display 2160 may be disposed on a surface of the body 2110 and display an image processed by the display controller 2150.

The power unit 2130 may receive a predetermined voltage from an external battery (not shown), divide the predetermined voltage into various voltage levels, and transmit divided voltages to the MP 2120, the function unit 2140, and the display controller 2150. The MP 2120 may receive a voltage from the power unit 2130 and control the function unit 2140 and the display 2160. The function unit 2140 may implement various functions of the electronic system 2100. For instance, when the electronic system 2100 is a smartphone, the function unit 2140 may include several elements capable of wireless communication functions, such as output of an image on the display 2160 or output of a voice to a speaker, by dialing or communication with an external device 2170. When the function unit 2140 includes a camera, the function unit 2140 may serve as an image processor.

In applied embodiments, when the electronic system 2100 is connected to a memory card to increase capacity, the function unit 2140 may exchange signals with the external device 2170 through a wired or wireless communication unit 2180. In addition, when the electronic system 2100 needs a universal serial bus (USB) to expand functions thereof, the function unit 2140 may serve as an interface controller. The function unit 2140 may include a mass storage device.

A semiconductor package similar to those described with reference to FIGS. 1 through 26 may be applied to the function unit 2140.

The foregoing description is illustrative of various possible embodiments and is not to be construed as limiting the inventive concepts. Although a few embodiments have been described, those skilled in the art will readily appreciate that many modifications are possible without materially departing from the novel teachings and advantages of the inventive concepts provided herein. Accordingly, all such modifications are intended to be included within the scope of the inventive concepts as defined in the claims. In the claims, means-plus-function clauses where present are intended to cover the structures described herein as performing the recited function, and not only structural equivalents but also equivalent structures.

What is claimed is:

1. A semiconductor package comprising:
a substrate;
a first semiconductor chip disposed on the substrate;
a second semiconductor chip disposed on the first semiconductor chip;
a heat spreader disposed above the first semiconductor chip; and
a thermal interfacial material (TIM) layer being in contact with the first semiconductor chip and the heat spreader, the TIM layer further covering one or more side surfaces of the second semiconductor chip.

2. The package of claim 1, wherein the second semiconductor chip comprises a first side surface and a second side surface,
wherein the TIM layer is in contact with both the first and second side surfaces of the second semiconductor chip.

3. The package of claim 1, wherein the TIM layer is formed between a top surface of the second semiconductor chip and the heat spreader.

4. The package of claim 1, wherein the TIM layer is in contact with a side surface of the first semiconductor chip.

5. The package of claim 1, wherein a bottom surface of the heat spreader is arranged at a level that is lower than a bottom surface of the second semiconductor chip.

6. The package of claim 1, wherein a distance between a bottom surface of the heat spreader and a top surface of the first semiconductor chip is smaller than a distance between the second semiconductor chip and the first semiconductor chip.

7. The package of claim 1, wherein a side surface of the first semiconductor chip is exposed to an outside of the semiconductor package.

8. The package of claim 1, wherein the first semiconductor chip includes through-silicon vias (TSVs) formed through the first semiconductor chip.

9. The package of claim 1, further comprising:
an underfill disposed between the substrate and the first semiconductor chip;
an under-bump metallurgy (UBM) disposed on the TSVs; and
bumps formed through the underfill and connected to the UBM and the substrate.

10. A semiconductor package comprising:
a first semiconductor chip;
a second semiconductor chip arranged on the first semiconductor chip; and
a heat spreader arranged above the first semiconductor chip and configured to cover top and side surfaces of the second semiconductor chip,
wherein a bottom surface of the heat spreader is arranged at a level lower than a bottom surface of the second semiconductor chip.

11. The package of claim 10, wherein the bottom surface of the heat spreader is in thermal communication with the first semiconductor chip.

12. The package of claim 10, wherein a distance between the bottom surface of the heat spreader and a top surface of the first semiconductor chip is smaller than a distance between the second semiconductor chip and the first semiconductor chip.

13. The package of claim 10, wherein the heat spreader has a greater width than the first semiconductor chip.

14. The package of claim 10, wherein side surfaces of the first semiconductor chip are exposed to an outside of the semiconductor package.

15. The package of claim 10, further comprising a thermal interfacial material (TIM) layer disposed between the heat spreader and a top surface of the first semiconductor chip.

16. A semiconductor package comprising:
a substrate;
a first semiconductor chip arranged on the substrate;
a second semiconductor chip arranged on the first semiconductor chip;
a heat spreader covering a top and side surfaces of the second semiconductor chip; and
a thermal interface material (TIM) arranged between the heat spreader and the second semiconductor chip.

17. The package of claim 16, wherein the TIM is further arranged between an edge portion of the first semiconductor chip and the heat spreader.

18. The package of claim 16, further comprising an underfill arranged between the first semiconductor chip and the substrate, said underfill having a middle coefficient of thermal expansion (CTE) between that of the first semiconductor chip and the substrate.

19. The package of claim 16, further comprising one or more additional semiconductor chips arranged above the second semiconductor chip, wherein the heat spreader is configured to cover the second and one or more additional semiconductor chips.

20. The package of claim 16, wherein the heat spreader is configured having a porous or lattice-type structure to help dissipate heat from the heat spreader.
